(19) United States
(12) Patent Application Publication
(10) Pub. No.: US 2025/0212695 A1
(43) Pub. Date: Jun. 26, 2025

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Jae Hoon Kim, Suwon-si (KR); Taesun Kim, Suwon-si (KR); Cheol Kim, Suwon-si (KR)

(21) Appl. No.: 18/790,737

(22) Filed: Jul. 31, 2024

(30) Foreign Application Priority Data
Dec. 20, 2023 (KR) 10-2023-0187365

(51) Int. Cl. H10N 50/80; G11C 11/16; H10B 61/00; H10N 50/01; H10N 50/10; H10N 50/85

(52) U.S. Cl. CPC H10N 50/80; H10B 61/10; H10B 61/22; H10N 50/01; H10N 50/10; G11C 11/161; H10N 50/85

(57) ABSTRACT

A semiconductor device includes a substrate that includes a cell region and a peripheral region, a plurality of data storage patterns on the cell region and each including a bottom electrode, a magnetic tunnel junction pattern, and a top electrode that are sequentially stacked, and a magnetic shield layer at the cell region and between the data storage patterns. The magnetic shield layer has a top surface that is recessed toward the substrate between the data storage patterns.

### CROSS-REFERENCE TO RELATED APPLICATION

This U.S. nonprovisional application claims priority under 35 U.S.C § 119 to Korean Patent Application No. 10-2023-0187365 filed on Dec. 20, 2023, in the Korean Intellectual Property Office, the disclosure of which is hereby incorporated by reference in its entirety.

### BACKGROUND

As electronic products trend toward high speed and/or low power consumption, high speed and low operating voltages are increasingly in demand for semiconductor memory devices incorporated in the electronic products. In order to meet these demands, magnetic memory devices have been developed as semiconductor memory devices. Because magnetic memory devices operate at high speeds and have nonvolatile characteristics, these devices have attracted considerable attention as the next-generation semiconductor memory devices.

In general, the magnetic memory device may include a magnetic tunnel junction (MTJ) pattern. The magnetic tunnel junction pattern includes two magnetic structures and an insulation layer interposed therebetween. The resistance of the magnetic tunnel junction pattern varies depending on magnetization directions of the two magnetic structures. For example, the magnetic tunnel junction pattern has high resistance when the magnetization directions of the two magnetic structures are anti-parallel and low resistance when the magnetization directions of the two magnetic structures are parallel. The magnetic memory device may write and read data using the resistance difference between the high and low resistances of the magnetic tunnel junction pattern.

### SUMMARY

The present disclosure provides a semiconductor device capable of reducing an effect of an external magnetic field and a method of fabricating the same.

The present disclosure provides a simplified method of fabricating a magnetoresistive RAM (MRAM) semiconductor device.

In a general aspect, a semiconductor device includes: a substrate that includes a cell region and a peripheral region; a plurality of data storage patterns on the cell region, each of the data storage patterns including a bottom electrode, a magnetic tunnel junction pattern, and a top electrode that are sequentially stacked; and a magnetic shield layer on the cell region and between the data storage patterns, the magnetic shield layer surrounding lateral surfaces of the data storage patterns. The magnetic shield layer may have a top surface that is recessed toward the substrate between the data storage patterns.

In another general aspect, a semiconductor device includes: a substrate that includes a cell region, a peripheral region, and a boundary region between the cell region and the peripheral region; a first lower dielectric layer on the substrate; a second lower dielectric layer on the first lower dielectric layer on the cell region and the boundary region; a plurality of data storage patterns on the second lower dielectric layer on the cell region, the data storage pattern including a bottom electrode, a magnetic tunnel junction pattern, and a top electrode that are sequentially stacked; a capping dielectric layer on the second lower dielectric layer, the capping dielectric layer surrounding lateral surfaces of the data storage patterns; a magnetic shield layer on the capping dielectric layer, the magnetic shield layer surrounding the lateral surfaces of the data storage patterns; a cell dielectric layer on the cell region and the boundary region, the cell dielectric layer covering the data storage patterns and the magnetic shield layer; a peripheral dielectric layer on the first lower dielectric layer on the peripheral region; and a plurality of peripheral wiring patterns in the peripheral dielectric layer, the peripheral wiring patterns penetrating the first lower dielectric layer on the peripheral region. The magnetic shield layer may have a top surface that is recessed toward the substrate between the data storage patterns.

In another general aspect, a method of fabricating a semiconductor device includes: providing a substrate that includes a cell region, a peripheral region, and a boundary region between the cell region and the peripheral region; forming on the substrate a wiring dielectric layer and a plurality of wiring structures that penetrate the wiring dielectric layer; sequentially stacking on the wiring dielectric layer a first lower dielectric layer and a second lower dielectric layer that extend from the cell region onto the boundary region and the peripheral region; forming on the cell region a plurality of data storage patterns each including a bottom electrode, a magnetic tunnel junction pattern, and a top electrode that are sequentially stacked on the second lower dielectric layer; forming a capping dielectric layer on the second lower dielectric layer on the cell region and the boundary region, the capping dielectric layer covering top surfaces and lateral surfaces of the data storage patterns; depositing a metal layer that conformally covers a top surface of the capping dielectric layer; and wet-etching a portion of the metal layer to form a magnetic shield layer having a top surface that is recessed toward the substrate between the data storage patterns.

### BRIEF DESCRIPTION OF DRAWINGS

FIG. 1 illustrates an example of a circuit diagram showing a unit memory cell of a semiconductor device.

FIG. 2 illustrates a plan view of an example of a semiconductor device.

FIG. 3A illustrates a cross-sectional view taken along line I-I′ of FIG. 2.

FIG. 3B illustrates a perspective view showing some components of the semiconductor device depicted in FIG. 2.

FIGS. 4A and 4B illustrate cross-sectional views showing examples of a magnetic tunnel junction pattern in a semiconductor device.

FIG. 5 illustrates an enlarged view showing section A of FIG. 3A.

FIGS. 6 to 14 illustrate cross-sectional views taken along line I-I′ of FIG. 2, showing an example of a method of fabricating a semiconductor device.

### DETAILED DESCRIPTION

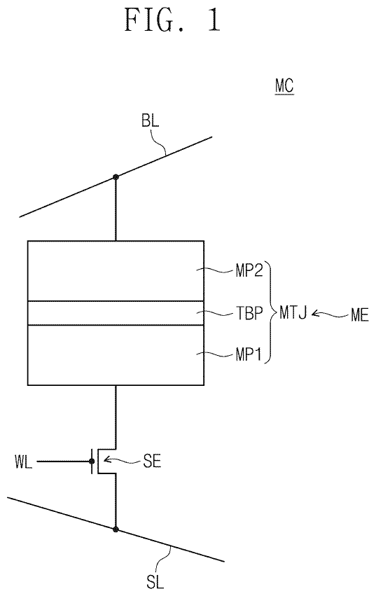

FIG. 1 illustrates an example of a circuit diagram showing a unit memory cell of a semiconductor device.

Referring to FIG. 1, a unit memory cell MC includes a memory element ME and a selection element SE. The memory element ME and the selection element SE may be electrically connected in series to each other. The memory element ME may be connected between a bit line BL and the selection element SE. The selection element SE may be connected between the memory element ME and a source line SL, and may be controlled by a word line WL. The selection element SE may include, for example, a bipolar transistor or a metal oxide semiconductor (MOS) field effect transistor.

The memory element ME may include a magnetic tunnel junction pattern MTJ including magnetic patterns MP1 and MP2 that are spaced apart from each other and also including a tunnel barrier pattern TBP between the magnetic patterns MP1 and MP2. One of the magnetic patterns MP1 and MP2, e.g., magnetic pattern MP1, may be a reference magnetic pattern having a magnetization direction that is fixed regardless of an external magnetic field under a normal use environment. The other of the magnetic patterns MP1 and MP2, e.g., magnetic pattern MP2, may be a free magnetic pattern whose magnetization direction is changed due to an external magnetic field between two stable magnetization directions. The magnetic tunnel junction pattern MTJ may have an electrical resistance whose value is much greater in a case that the magnetization directions of the reference magnetic pattern and the free magnetic pattern are antiparallel to each other than in a case that the magnetization directions of the reference magnetic pattern and the free magnetic pattern are parallel to each other. For example, the electrical resistance of the magnetic tunnel junction pattern MTJ may be controlled by changing the magnetization direction of the free magnetic pattern. The memory element ME may use the difference in electrical resistance dependent on the magnetization directions of the reference magnetic pattern and the free magnetic pattern, which mechanism may cause the unit memory cell MC to store data therein.

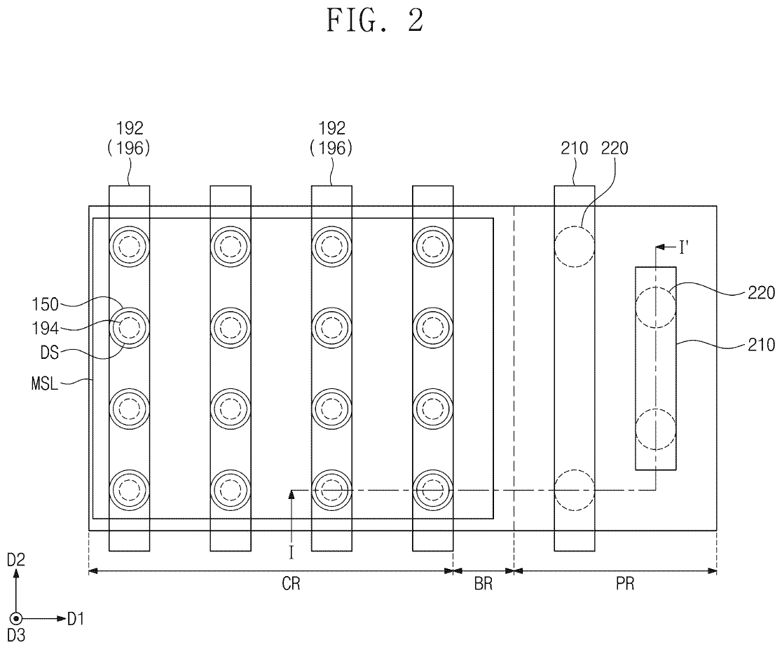

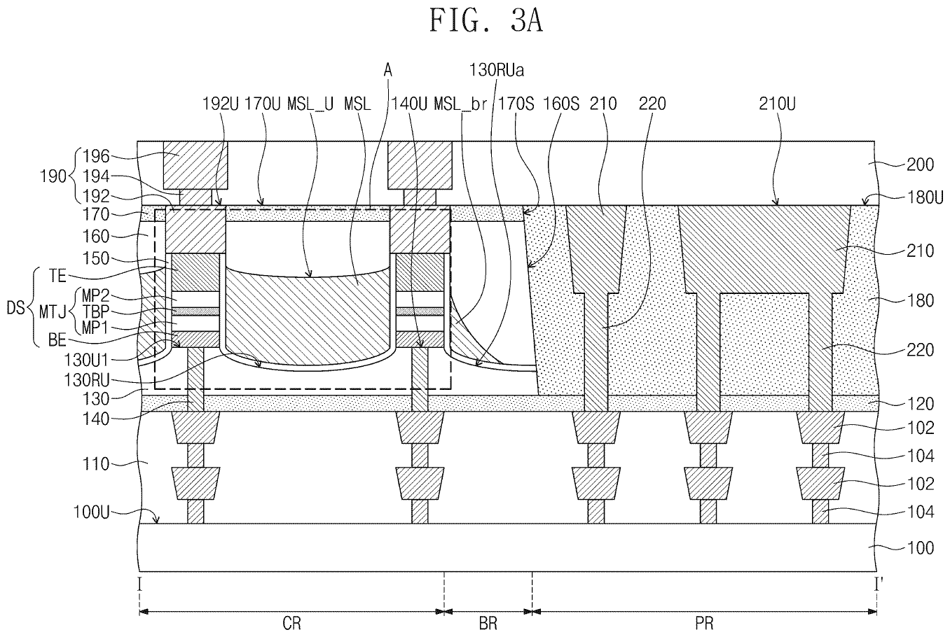

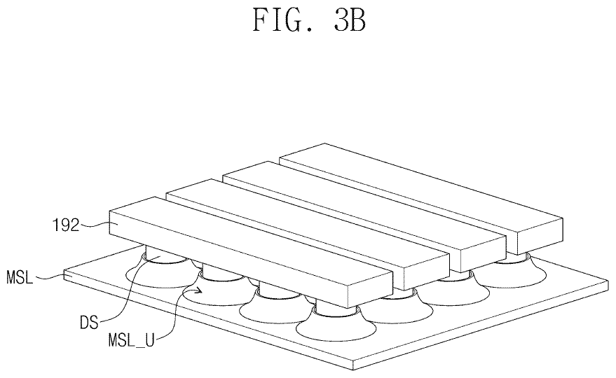

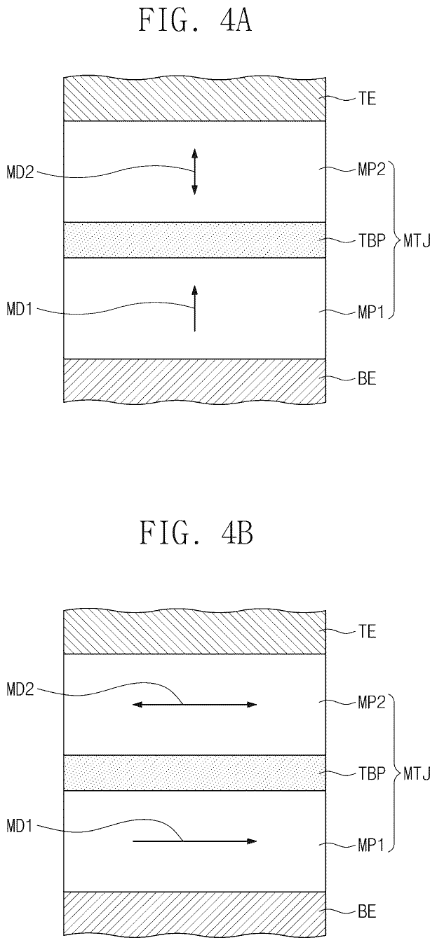

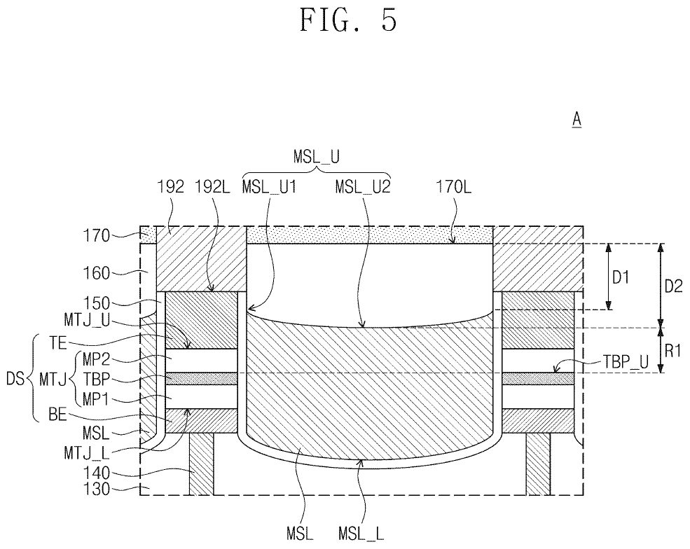

FIG. 2 illustrates a plan view of an example of semiconductor device. FIG. 3A illustrates a cross-sectional view taken along line I-I′ of FIG. 2. FIG. 3B illustrates a perspective view showing some components of the semiconductor device depicted in FIG. 2. FIGS. 4A and 4B illustrate cross-sectional views showing examples of a magnetic tunnel junction pattern in a semiconductor device. FIG. 5 illustrates an enlarged view showing section A of FIG. 3A.

Referring to FIGS. 2, 3A, and 3B, a substrate 100 includes a cell region CR, a peripheral region PR, and a boundary region BR between the cell region CR and the peripheral region PR. The substrate 100 may be a semiconductor substrate including silicon (Si), silicon-on-insulator (SOI), silicon-germanium (SiGe), germanium (Ge), or gallium-arsenic (GaAs). The cell region CR may be one area of the substrate 100 on which are provided the memory cells MC of FIG. 1, and the peripheral region PR may be another area of the substrate 100 on which are provided peripheral circuits for driving the memory cells MC. The boundary region BR may be still another area of the substrate 100 provided between the cell region CR and the peripheral region PR.

A wiring structure, e.g., wirings lines 102 and wiring contacts 104, may be disposed on the substrate 100. The wiring structure may be disposed on the cell region CR and the peripheral region PR of the substrate 100. The wiring structure may include wiring lines 102 vertically spaced apart from the substrate 100 and wiring contacts 104 connected to the wiring lines 102. The wiring lines 102 may be spaced apart from a top surface 100U of the substrate 100 along a direction perpendicular to the top surface 100U of the substrate 100. The wiring contacts 104 may be disposed between the substrate 100 and the wiring lines 102. Each of the wiring lines 102 may be electrically connected to the substrate 100 through a corresponding one of the wiring contacts 104. The wiring lines 102 and the wiring contacts 104 may include metal (e.g., copper).

Selection elements (see SE of FIG. 1) may be disposed on the cell region CR of the substrate 100, and peripheral transistors constituting the peripheral circuits may be disposed on the peripheral region PR of the substrate 100. The selection elements and the peripheral transistors may be, for example, field effect transistors. Each of the wiring lines 102 may be electrically connected through a corresponding one of the wiring contacts 104 to one terminal (e.g., a source terminal, a drain terminal, or a gate terminal) of a corresponding one of either the selection elements or the peripheral transistors.

A wiring dielectric layer 110 may be disposed on the substrate 100 to cover the wiring structure, e.g., wirings lines 102 and wiring contacts 104. The wiring dielectric layer 110 may be disposed on the cell region CR of the substrate 100, and may extend onto the boundary region BR and the peripheral region PR of the substrate 100. The wiring dielectric layer 110 may expose top surfaces of uppermost ones of the wiring lines 102. For example, the wiring dielectric layer 110 may have a top surface substantially coplanar with those of the uppermost wiring lines 102. The wiring dielectric layer 110 may include, for example, one or more of silicon oxide, silicon nitride, and silicon oxynitride.

A first lower dielectric layer 120 may be disposed on the wiring dielectric layer 110 and may cover the exposed top surfaces of the uppermost wiring lines 102. The first lower dielectric layer 120 may be disposed on the wiring dielectric layer 110 on the cell region CR, and may extend onto the wiring dielectric layer 110 on the boundary region BR and the peripheral region PR. The first lower dielectric layer 120 may include, for example, one or more of silicon oxide, silicon nitride, and silicon oxynitride.

A second lower dielectric layer 130 may be disposed on the first lower dielectric layer 120. The second lower dielectric layer 130 may be disposed on the first lower dielectric layer 120 on the cell region CR, and may extend onto the first lower dielectric layer 120 on the boundary region BR. The second lower dielectric layer 130 may include, for example, one or more of silicon oxide, silicon nitride, and silicon oxynitride.

The second lower dielectric layer 130 may include a different material from that of the first lower dielectric layer 120. The first lower dielectric layer 120 may include silicon carbon nitride (e.g., SiCN), and the second lower dielectric layer 130 may include silicon oxide (e.g., tetraethoxysilane (TEOS)).

Data storage patterns DS may be disposed on the second lower dielectric layer 130 on the cell region CR. The data storage patterns DS may be spaced apart from each other in a first direction D1 and a second direction D2 that intersect each other and are parallel to the top surface 100U of the substrate 100.

The second lower dielectric layer 130 on the cell region CR may have a top surface 130RU that is recessed toward the substrate 100 between the data storage patterns DS. The recessed top surface 130RU of the second lower dielectric layer 130 on the cell region CR may be located at a level lower than that of an uppermost surface 130U1 of the second lower dielectric layer 130 on the cell region CR. In this description, the term “level” may refer to a height from the top surface 100U of the substrate 100 in a third direction D3 perpendicular to the top surface 100U of the substrate 100.

The second lower dielectric layer 130 on the boundary region BR may have a top surface 130RUa that is recessed toward the substrate 100. The recessed top surface 130RUa of the second lower dielectric layer 130 on the boundary region BR may be located at a height lower than that of the uppermost surface 130U1 of the second lower dielectric layer 130 on the cell region CR. In some implementations, the recessed top surface 130RUa of the second lower dielectric layer 130 on the boundary region BR may be located at the same height as that of the recessed top surface 130RU of the second lower dielectric layer 130 on the cell region CR.

Lower electrode contacts 140 may be disposed in the second lower dielectric layer 130 on the cell region CR and may be spaced apart from each other in the first direction D1 and the second direction D2. The lower electrode contacts 140 may be correspondingly disposed below and electrically connected to the data storage patterns DS. Each of the lower electrode contacts 140 may penetrate the first and second lower dielectric layers 120 and 130 on the cell region CR, and may be connected to a corresponding one of the uppermost wiring lines 102. Each of the data storage patterns DS may be electrically connected to one terminal (e.g., a drain terminal) of a corresponding selection element through a corresponding lower electrode contact 140 and a corresponding uppermost wiring line 102.

The lower electrode contacts 140 may have their top surfaces 140U located at a height higher than that of the recessed top surface 130RU of the second lower dielectric layer 130 on the cell region CR. The top surfaces 140U of the lower electrode contacts 140 may be located at the same height as that of the uppermost surface 130U1 of the second lower dielectric layer 130 on the cell region CR. The recessed top surface 130RUa of the second lower dielectric layer 130 on the boundary region BR and a top surface 130U2 of the second lower dielectric layer 130 on the peripheral region PR may be located at a height lower than that of the top surfaces 140U of the lower electrode contacts 140.

The lower electrode contacts 140 may include at least one of the following: doped semiconductor materials (e.g., doped silicon), metals (e.g., one or more of tungsten, titanium, and tantalum), metal-semiconductor compounds (e.g., metal silicide), and conductive metal nitrides (e.g., one or more of titanium nitride, tantalum nitride, and tungsten nitride).

Each of the data storage patterns DS may include a bottom electrode BE, a magnetic tunnel junction pattern MTJ, and a top electrode TE that are stacked, e.g., sequentially stacked, in the third direction D3 on the second lower dielectric layer 130. The magnetic tunnel junction pattern MTJ may be disposed between the bottom electrode BE and the top electrode TE. The lower electrode contacts 140 may be correspondingly connected to the bottom electrodes BE of the data storage patterns DS. The bottom electrode BE of each of the data storage patterns DS may be in contact with the top surface 140U of one of the lower electrode contacts 140 and with the uppermost surface 130U1 of the second lower dielectric layer 130 on the cell region CR.

The magnetic tunnel junction pattern MTJ may include a first magnetic pattern MP1, a second magnetic pattern MP2, and a tunnel barrier pattern TBP between the first magnetic pattern MP1 and the second magnetic pattern MP2. The first magnetic pattern MP1 may be disposed between the bottom electrode BE and the tunnel barrier pattern TBP, and the second magnetic pattern MP2 may be disposed between the top electrode TE and the tunnel barrier pattern TBP. The bottom electrode BE may include, for example, conductive metal nitride (e.g., titanium nitride or tantalum nitride). The top electrode TE may include one or more of the following: metal (e.g., Ta, W, Ru, or Ir) and conductive metal nitride (e.g., TiN).

Referring to FIGS. 4A and 4B, the first magnetic pattern MP1 may be a reference layer having a magnetization direction MD1 that is fixed in one direction, and the second magnetic pattern MP2 may be a free layer having a magnetization direction MD2 that can be changed to be parallel or antiparallel to the magnetization direction MD1 of the first magnetic pattern MP1. FIGS. 4A and 4B show an example in which the second magnetic pattern MP2 is a free layer, but the present disclosure is not limited thereto. For example, the first magnetic pattern MP1 may be a free layer, and the second magnetic pattern MP2 may be a reference layer.

Referring to FIG. 4A, for example, the magnetization directions MD1 and MD2 of the first and second magnetic patterns MP1 and MP2 may be perpendicular to an interface between the tunnel barrier pattern TBP and the second magnetic pattern MP2, e.g., be “perpendicular magnetic”. In other words, the magnetic patterns MP1 and MP2 have perpendicular magnetic anisotropy. In this case, each of the first and second magnetic patterns MP1 and MP2 may include one or more of the following: an intrinsic perpendicular magnetic material and an extrinsic perpendicular magnetic material. The intrinsic perpendicular magnetic material may include a material having perpendicular magnetization properties found even in the absence of an external factor. The intrinsic perpendicular magnetic material may include at least one of the following: a perpendicular magnetic material (e.g., CoFeTb, CoFeGd, CoFeDy), a perpendicular magnetic material having an L1₀ structure, CoPt of a hexagonal close-packed (HCP) lattice structure, and a perpendicular magnetic structure. The perpendicular magnetic material having the L1₀ structure may include one or more of the following: FePt of the L1₀ structure, FePd of the L1₀ structure, CoPd of the L1₀ structure, and CoPt of the L1₀ structure. The perpendicular magnetic structure may include magnetic layers and nonmagnetic layers that are alternately and repeatedly stacked. For example, the perpendicular magnetic structure may include one or more of the following: (Co/Pt)n, (CoFe/Pt)n, (CoFe/Pd)n, (Co/Pd)n, (Co/Ni)n, (CoNi/Pt)n, (CoCr/Pt)n, and (CoCr/Pd)ₙ (where, n is the number of stacked layers). The extrinsic perpendicular magnetic material may include a material having intrinsic horizontal magnetization properties or perpendicular magnetization properties caused by an external factor. For example, the extrinsic perpendicular magnetic material may have perpendicular magnetization properties due to magnetic anisotropy induced by junction between the tunnel barrier pattern TBP and the first magnetic pattern MP1 (or the second magnetic pattern MP2). The extrinsic perpendicular magnetic material may include, for example, CoFeB.

Referring to FIG. 4B, for another example, the magnetization directions MD1 and MD2 of the first and second magnetic patterns MP1 and MP2 may be parallel to the interface between the tunnel barrier pattern TBP and the second magnetic pattern MP2. In this case, each of the first and second magnetic patterns MP1 and MP2 may include a ferromagnetic material. The first magnetic pattern MP1 may further include an antiferromagnetic material for fixing a magnetization direction of the ferromagnetic material in the first magnetic pattern MP1.

Each of the first magnetic pattern MP1 and the second magnetic pattern MP2 may include a Heusler alloy including Co. The tunnel barrier pattern TBP may include one or more of the following: a magnesium (Mg) oxide layer, a titanium (Ti) oxide layer, an aluminum (Al) oxide layer, a magnesium-zinc (MgZn) oxide layer, and a magnesium-boron (MgB) oxide layer.

Referring back to FIGS. 2, 3A, and 3B, a capping dielectric layer 150 may be disposed on the second lower dielectric layer 130 on the cell region CR. The capping dielectric layer 150 may conformally cover a lateral surface of each of the data storage patterns DS and the recessed top surface 130RU of the second lower dielectric layer 130 on the cell region CR. The capping dielectric layer 150 may have a top surface that is recessed toward the substrate 100 between the data storage patterns DS. When viewed in plan, the capping dielectric layer 150 may surround the lateral surface of each of the data storage patterns DS. The capping dielectric layer 150 may extend onto the second lower dielectric layer 130 on the boundary region BR, and may conformally cover the recessed top surface 130RUa of the second lower dielectric layer 130 on the boundary region BR.

The capping dielectric layer 150 may conformally cover lateral surfaces of the bottom electrode BE, the magnetic tunnel junction pattern MTJ, and the top electrode TE. When viewed in plan, the capping dielectric layer 150 may surround the lateral surfaces of the bottom electrode BE, the magnetic tunnel junction pattern MTJ, and the top electrode TE. The capping dielectric layer 150 may include nitride (e.g., silicon nitride).

A magnetic shield layer MSL may be formed on the cell region CR. The magnetic shield layer MSL may extend from the cell region CR to the boundary region BR, and one end MSL_br of the magnetic shield layer MSL may be positioned on the boundary region BR. The magnetic shield layer MSL may not extend onto the peripheral region PR.

The data storage patterns DS, which are two-dimensionally spaced apart from each other in the first direction D1 and the second direction D2, may penetrate the magnetic shield layer MSL. The magnetic shield layer MSL may surround the lateral surfaces of the data storage patterns DS and a sidewall of the capping dielectric layer 150. For example, the magnetic shield layer MSL may have a unitary plate shape with through holes that are penetrated by the data storage patterns DS, e.g., the data storage patterns DS extend through the through holes.

The magnetic shield layer MSL may include a material that exhibits ferromagnetism. For example, the magnetic shield layer MSL may include one or more of the following: cobalt (Co), iron (Fe), nickel (Ni), and rare-earth metal. The magnetic shield layer MSL may be a ferromagnetic substance including a ferromagnetic material, and most of magnetic flux due to an external magnetic field may be allowed to pass through the magnetic shield layer MSL when a magnetic field is formed outside a semiconductor device. Therefore, the magnetic flux that passes through the data storage pattern DS may be reduced due to the external magnetic field, and the magnetic tunnel junction pattern MTJ may be less affected by the external magnetic field.

Referring to FIGS. 2, 3A, and 5, the magnetic shield layer MSL has a top surface MSL_U that is recessed toward the substrate 100 between the data storage patterns DS. For example, the recessed top surface MSL_U may include a first part MSL_U1 in contact with the sidewall of the capping dielectric layer 150, and the first part MSL_U1 may be located at a maximum level on the recessed top surface MSL_U. In addition, the recessed top surface MSL_U may include a second part MSL_U2 that is spaced apart from the capping dielectric layer 150 and is positioned at a center of the recessed top surface MSL_U, and the second part MSL_U2 may be located at a level lower than that of the first part MSL_U1. For example, the second part MSL_U2 of the recessed top surface MSL_U of the magnetic shield layer MSL may be located at a height higher by at least about 10 nm than that of a top surface TBP_U of the tunnel barrier pattern TBP (or, R1≥10 nm). In such a configuration, the first part MSL_U1 of the recessed top surface MSL_U of the magnetic shield layer MSL may be located at a height lower by at least about 5 nm than that of a bottom surface 170L of the upper dielectric layer 170 (or, D1≥5 nm). Therefore, the second part MSL_U2 may be located at a height lower by about 5 nm than that of the bottom surface 170L of the upper dielectric layer 170 (or, D2≥5 nm). The recessed top surface MSL_U of the magnetic shield layer MSL may be located at a level that decreases in a direction from the cell region CR toward the peripheral region PR.

Between the data storage patterns DS that are adjacent to each other in the first direction D1 or the second direction D2, the recessed top surface MSL_U of the magnetic shield layer MSL may be located at a level higher than that of a top surface MTJ_U of the magnetic tunnel junction pattern MTJ included in the data storage pattern DS. In addition, a bottom surface MSL_L of the magnetic shield layer MSL may be located at a level lower than that of a bottom surface MTJ_L of the magnetic tunnel junction pattern MTJ. Therefore, between neighboring magnetic tunnel junction patterns MTJ, the magnetic shield layer MSL may be formed to have a volume greater than that of the magnetic tunnel junction pattern MTJ. Moreover, the magnetic shield layer MSL may surround the lateral surface of the magnetic tunnel junction pattern MTJ, and may be a ferromagnetic substance whose magnetism is stronger than that of the magnetic tunnel junction pattern MTJ to thereby allow passage of magnetic flux due to an external magnetic field.

The recessed top surface MSL_U of the magnetic shield layer MSL may be located at a level lower than that of a bottom surface 192L of a first cell conductive line 192 which will be discussed below. For example, the magnetic shield layer MSL may be spaced apart from the first cell conductive line 192, and may not be electrically connected to any of the first cell conductive line 192, conductive contacts 194 on the first cell conductive line 192, and second cell conductive lines 196 which will be discussed below.

Referring back to FIGS. 2 and 3A, a cell dielectric layer 160 may be disposed on the second lower dielectric layer 130 on the cell region CR, and may cover the data storage patterns DS and the magnetic shield layer MSL. The cell dielectric layer 160 may fill a space between the data storage patterns DS. The capping dielectric layer 150 may be interposed between the cell dielectric layer 160 and the lateral surface of each of the data storage patterns DS, and may extend between the cell dielectric layer 160 and the recessed top surface 130RU of the second lower dielectric layer 130 on the cell region CR. The cell dielectric layer 160 may extend onto the second lower dielectric layer 130 on the boundary region BR. The capping dielectric layer 150 may extend between the cell dielectric layer 160 and the recessed top surface 130RUa of the second lower dielectric layer 130 on the boundary region BR. The cell dielectric layer 160 may include, for example, one or more of silicon oxide, silicon nitride, and silicon oxynitride.

The upper dielectric layer 170 may be disposed on the cell dielectric layer 160 on the cell region CR. The upper dielectric layer 170 may extend onto the cell dielectric layer 160 on the boundary region BR. The upper dielectric layer 170 may include a material different from that of the cell dielectric layer 160. For example, the cell dielectric layer 160 may include silicon oxide, and the upper dielectric layer 170 may include silicon carbon nitride (e.g., SiCN).

A peripheral dielectric layer 180 may be disposed on the second lower dielectric layer 130 on the peripheral region PR. The peripheral dielectric layer 180 may be in contact with a top surface of the first lower dielectric layer 120 on the peripheral region PR. The peripheral dielectric layer 180 may be in contact with a lateral surface 160S of the cell dielectric layer 160 and a lateral surface 170S of the upper dielectric layer 170. The peripheral dielectric layer 180 may be in contact with a lateral surface of the capping dielectric layer 150.

A top surface 180U of the peripheral dielectric layer 180 may be located at the same height as that of a top surface 170U of the upper dielectric layer 170. The top surface 180U of the peripheral dielectric layer 180 may be coplanar with the top surface 170U of the upper dielectric layer 170.

For example, the peripheral dielectric layer 180 may include a material the same as or similar to that of the cell dielectric layer 160. For another example, the peripheral dielectric layer 180 may include a different material from that of the cell dielectric layer 160, and may include a dielectric material whose dielectric constant (k) is less than that of the cell dielectric layer 160.

On the cell region CR, bit lines 190 (see BL of FIG. 1) may be disposed on the data storage patterns DS. Each of the bit lines BL may include a first cell conductive line 192, a corresponding conductive contact 194, and a second cell conductive line 196.

The first cell conductive lines 192 may extend in the second direction D2 and may be spaced apart from each other in the first direction D1. Each of the first cell conductive lines 192 may have a linear shape that extends in the second direction D2. Each of the first cell conductive lines 192 may be electrically connected to corresponding data storage patterns DS that are spaced apart from each other in the second direction D2. The data storage patterns DS that are spaced apart from each other in the first direction D1 may be electrically connected to corresponding first cell conductive lines 192.

Each of the first cell conductive lines 192 may penetrate the upper dielectric layer 170, and may also penetrate an upper portion of the cell dielectric layer 160 to come into connection with a corresponding data storage pattern DS. A bottom surface 192L of each of the first cell conductive lines 192 may be in contact with the top electrode TE of the corresponding data storage pattern DS. The first cell conductive lines 192 may have their top surfaces 192U that are located at the same height as that of the top surface 170U of the upper dielectric layer 170 and are coplanar with the top surface 170U of the upper dielectric layer 170. The first cell conductive lines 192 may include a conductive material, such as metal (e.g., copper).

Peripheral conductive line parts 210 may be disposed in the peripheral dielectric layer 180 and on the first lower dielectric layer 120 on the peripheral region PR. The peripheral dielectric layer 180 may cover the peripheral conductive line parts 210. The peripheral conductive line parts 210 may have their top surfaces 210U that are exposed without being covered with the peripheral dielectric layer 180. The top surfaces 210U of the peripheral conductive line parts 210 may be located at the same height as that of the top surface 180U of the peripheral dielectric layer 180, and may be coplanar with the top surface 180U of the peripheral dielectric layer 180. The top surfaces 210U of the peripheral conductive line parts 210 may be coplanar with or located at the same height as that of the top surface 180U of the peripheral dielectric layer 180, the top surfaces 192U of the first cell conductive lines 192, and the top surface 170U of the upper dielectric layer 170.

Peripheral wiring patterns, e.g., peripheral conductive line parts 210 and peripheral conductive contact parts 220, may be disposed on the peripheral region PR. Each of the peripheral wiring patterns may include the peripheral conductive line part 210 and a peripheral conductive contact part 220 disposed below the peripheral conductive line part 210. The peripheral conductive contact part 220 may be electrically connected to the peripheral conductive line part 210. Each of the peripheral conductive contact parts 220 and its corresponding peripheral conductive line part 210 may be in contact with each other without a boundary therebetween. Each of the peripheral conductive contact parts 220 and its corresponding peripheral conductive line part 210 may be connected to each other into a single unitary piece. Each of the peripheral conductive contact parts 220 may penetrate a lower portion of the peripheral dielectric layer 180. Each of the peripheral conductive contact parts 220 may penetrate the first lower dielectric layer 120 on the peripheral region PR, and may be electrically connected to a corresponding one of the uppermost wiring lines 102. Each of the peripheral conductive line parts 210 may be electrically connected through a corresponding peripheral conductive contact part 220 and a corresponding uppermost wiring line 102 to one terminal (e.g., a source terminal, a drain terminal, or a gate terminal) of a corresponding peripheral transistor.

The peripheral conductive line parts 210 and the peripheral conductive contact parts 220 may include a conductive material, such as metal (e.g., copper). The first cell conductive lines 192, the peripheral conductive line parts 210, and the peripheral conductive contact parts 220 may include the same material.

An upper interlayer dielectric layer 200 may be disposed on the cell region CR, the boundary region BR, and the peripheral region PR, and may cover the top surface 170U of the upper dielectric layer 170, the top surfaces 192U of the first cell conductive lines 192, the top surface 180U of the peripheral dielectric layer 180, and the top surfaces 210U of the peripheral conductive line parts 210. The upper interlayer dielectric layer 200 may include, for example, one or more of silicon oxide, silicon nitride, and silicon oxynitride.

The second cell conductive lines 196 may be disposed in the upper interlayer dielectric layer 200 on the cell region CR. The second cell conductive lines 196 may extend in the second direction D2 and may be spaced apart from each other in the first direction D1. The second cell conductive lines 196 may correspondingly overlap vertically (e.g., in the third direction D3) with the first cell conductive lines 192. The conductive contacts 194 may be disposed in the upper interlayer dielectric layer 200 on the cell region CR, and may be placed between the first cell conductive lines 192 and the second cell conductive lines 196. Each of the first cell conductive lines 192 may be electrically connected through a corresponding one of the conductive contacts 194 to one of the second cell conductive lines 196. The conductive contacts 194 and the second cell conductive lines 196 may include a conductive material, such as metal (e.g., copper).

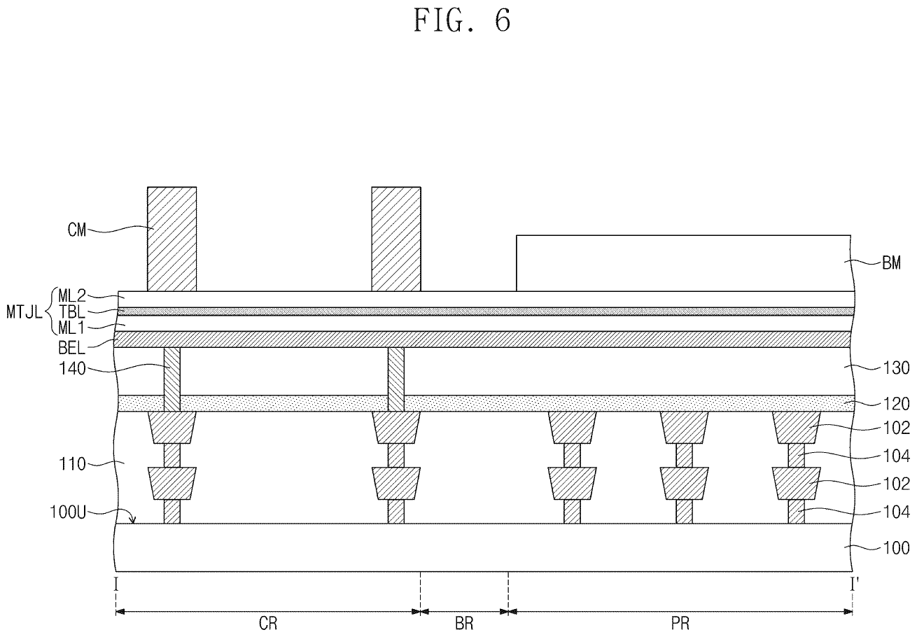

FIGS. 6 to 14 illustrate cross-sectional views taken along line I-I′ of FIG. 2, showing an example of a method of fabricating a semiconductor device. For brevity of description, omission will be made to avoid a duplicate explanation of the semiconductor device mentioned with reference to FIGS. 1 to 3A, 4A, 4B, and 5.

Referring to FIGS. 2 and 6, a substrate 100 includes a cell region CR, a peripheral region PR, and a boundary region BR between the cell region CR and the peripheral region PR. Selection elements (see SE of FIG. 1) and peripheral transistors may be formed on the substrate 100, and a wiring structure, e.g., wirings lines 102 and wiring contacts 104, may be formed on the selection elements and the peripheral transistors. The wiring structure may include wiring lines 102 that are spaced vertically (e.g., in a third direction D3) apart from the substrate 100 and wiring contacts 104 connected to the wiring lines 102. Each of the wiring lines 102 may be electrically connected through a corresponding one of the wiring contacts 104 to one terminal (e.g., a source terminal, a drain terminal, or a gate terminal) of either a corresponding selection element or a corresponding peripheral transistors.

A wiring dielectric layer 110 may be formed on the substrate 100. The wiring dielectric layer 110 may expose top surfaces of uppermost ones of the wiring lines 102. The wiring dielectric layer 110 may be positioned on the cell region CR, the boundary region BR, and the peripheral region PR.

A first lower dielectric layer 120 that extends from the cell region CR onto the boundary region BR and the peripheral region PR may be stacked on the wiring dielectric layer 110. The first lower dielectric layer 120 may cover the exposed top surfaces of the uppermost wiring lines 102.

A second lower dielectric layer 130 may be stacked on the first lower dielectric layer 120. The second lower dielectric layer 130 may extend from the cell region CR onto the boundary region BR and the peripheral region PR.

Lower electrode contacts 140 may be formed in the second lower dielectric layer 130 on the cell region CR. Each of the lower electrode contacts 140 may penetrate the first and second lower dielectric layers 120 and 130 on the cell region CR, and may be electrically connected to one of the uppermost wiring lines 102. The formation of the lower electrode contacts 140 may include, for example, forming lower contact holes that penetrate the first and second lower dielectric layers 120 and 130 on the cell region CR, forming on the second lower dielectric layer 130 a lower contact layer that fills the lower contact holes, and planarizing the lower contact layer until a top surface of the second lower dielectric layer 130 is exposed. In the planarization process, the lower electrode contacts 140 may be locally formed in corresponding lower contact holes.

A lower electrode layer BEL and a magnetic tunnel junction layer MTJL may be sequentially stacked on the second lower dielectric layer 130. The lower electrode layer BEL and the magnetic tunnel junction layer MTJL may be formed on the second lower dielectric layer 130 on the cell region CR, and may extend onto the second lower dielectric layer 130 on the boundary region BR and the peripheral region PR. The magnetic tunnel junction layer MTJL may include a first magnetic layer ML1, a tunnel barrier layer TBL, and a second magnetic layer ML2 that are sequentially stacked on the lower electrode layer BEL. The lower electrode layer BEL and the magnetic tunnel junction layer MTJL may be formed by, for example, sputtering, chemical vapor deposition, or atomic layer deposition.

Conductive mask patterns CM may be formed on the magnetic tunnel junction layer MTJL on the cell region CR. The conductive mask patterns CM may define regions on which magnetic tunnel junction patterns MTJ will be formed as discussed below. The conductive mask patterns CM may be spaced apart from each other in a first direction D1 and a second direction D2, and may include one or more of a metal (e.g., Ta, W, Ru, or Ir) or conductive metal nitride (e.g., TiN).

A blocking mask pattern BM may be formed on the magnetic tunnel junction layer MTJL on the peripheral region PR. The blocking mask pattern BM may cover the magnetic tunnel junction layer MTJL on the peripheral region PR, and may expose the magnetic tunnel junction layer MTJL on the boundary region BR. The blocking mask pattern BM may include, for example, one or more of silicon nitride and metal nitride.

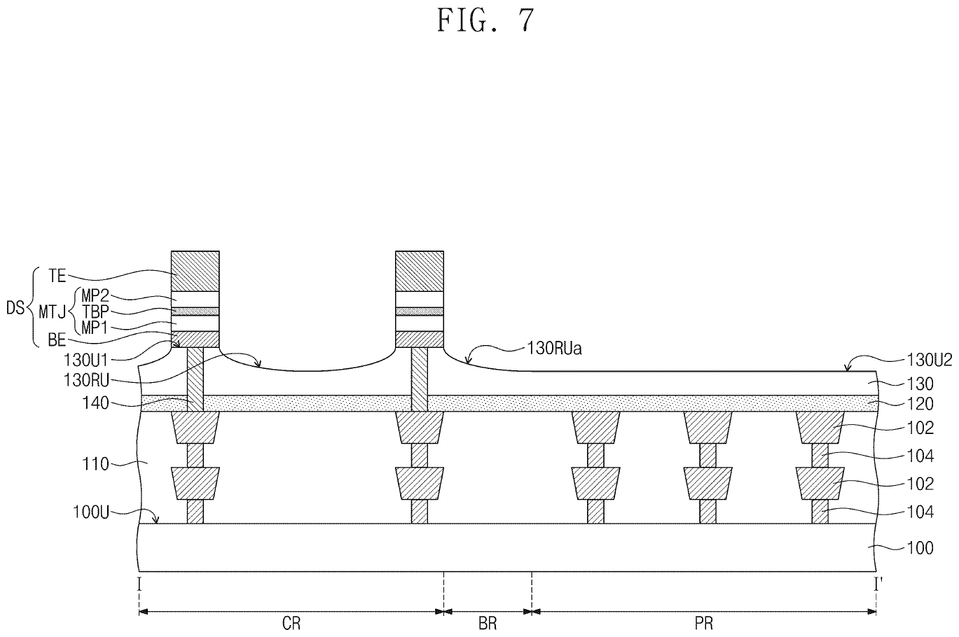

Referring to FIGS. 2 and 7, data storage patterns DS include a bottom electrode BE, a magnetic tunnel junction pattern MTJ, and a top electrode TE that are sequentially stacked on the second lower dielectric layer 130. For example, the conductive mask patterns CM may be used as an etch mask to perform a first etching process that etches the magnetic tunnel junction layer MTJL and the lower electrode layer BEL. The first etching process may be, for example, an ion beam etching process that uses an ion beam. The ion beam may include inert ions. In the first etching process, the magnetic tunnel junction layer MTJL and the lower electrode layer BEL may be etched to respectively form the magnetic tunnel junction pattern MTJ and the bottom electrode BE.

The etching of the magnetic tunnel junction layer MTJL may include sequentially etching the second magnetic layer ML2, the tunnel barrier layer TBL, and the first magnetic layer ML1. The second magnetic layer ML2, the tunnel barrier layer TBL, and the first magnetic layer ML1 may be etched to respectively form a second magnetic pattern MP2, a tunnel barrier pattern TBP, and a first magnetic pattern MP1. The conductive mask pattern CM may remain on the magnetic tunnel junction pattern MTJ after the first etching process, and the remainder of the conductive mask pattern CM may be defined as the top electrode TE. The bottom electrode BE, the magnetic tunnel junction pattern MTJ, and the top electrode TE may be called the data storage pattern DS. A plurality of data storage patterns DS may be correspondingly formed on the lower electrode contacts 140, and may be spaced apart from each other in the first direction D1 and the second direction D2.

The first etching process may recess an upper portion of the second lower dielectric layer 130 between the plurality of data storage patterns DS. Therefore, the second lower dielectric layer 130 on the cell region CR may have a top surface 130RU that is recessed toward the substrate 100. The recessed top surface 130RU of the second lower dielectric layer 130 on the cell region CR may be located at a height lower than that of top surfaces 140U of the lower electrode contacts 140 and that of an uppermost surface 130U1 of the second lower dielectric layer 130 on the cell region CR.

The blocking mask pattern BM may be removed during the first etching process, and the magnetic tunnel junction layer MTJL and the lower electrode layer BEI on the boundary region BR and the peripheral region PR may also be removed during the first etching process. In addition, the first etching process may recess an upper portion of the second lower dielectric layer 130 on the boundary region BR.

A top surface 130U2 of the second lower dielectric layer 130 on the peripheral region PR may be located at a height lower than that of the uppermost surface 130U1 of the second lower dielectric layer 130 on the cell region CR. A thickness (e.g., in the third direction D3) of the blocking mask pattern BM may be adjusted such that the top surface 130U2 of the second lower dielectric layer 130 on the peripheral region PR may be controlled to lie at a height higher or lower than that of the recessed top surface 130RU of the second lower dielectric layer 130 on the cell region CR.

The second lower dielectric layer 130 on the boundary region BR may have a recessed top surface 130RUa located at a height lower than that of the uppermost surface 130U1 of the second lower dielectric layer 130 on the cell region CR. The blocking mask pattern BM may not be provided on the boundary region BR.

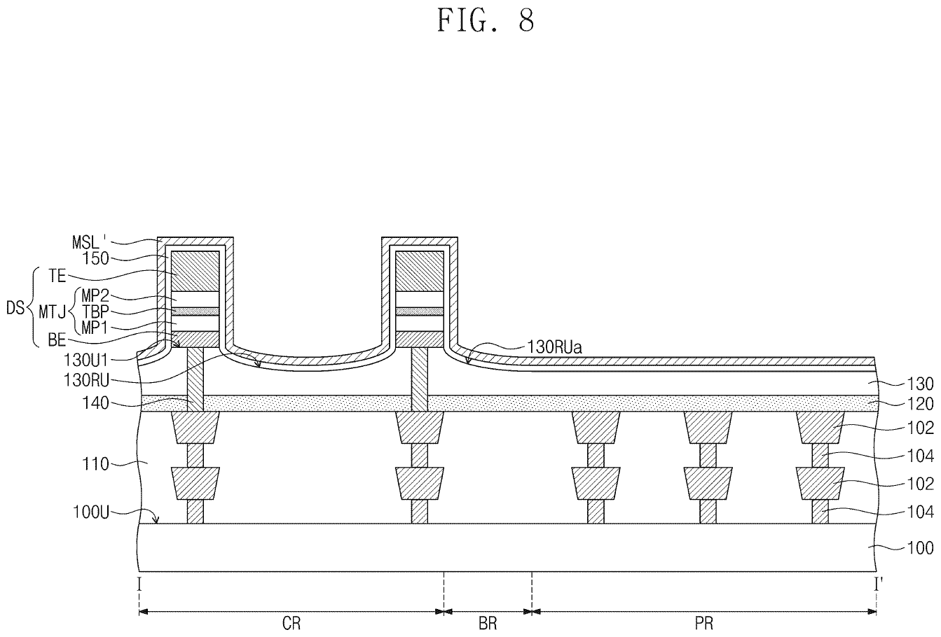

Referring to FIGS. 2 and 8, a capping dielectric layer 150 extends from the second lower dielectric layer 130 on the cell region CR toward the second lower dielectric layer 130 on the boundary region BR. The capping dielectric layer 150 may cover top surfaces and lateral surfaces of the data storage patterns DS. On the cell region CR, the capping dielectric layer 150 may conformally cover the top and lateral surfaces of each of the data storage patterns DS. The capping dielectric layer 150 may conformally cover the recessed top surface 130RU of the second lower dielectric layer 130 on the cell region CR. The capping dielectric layer 150 may extend onto the second lower dielectric layer 130 on the boundary region BR, and may conformally cover the recessed top surface 130RUa of the second lower dielectric layer 130 on the boundary region BR. The capping dielectric layer 150 may extend onto the second lower dielectric layer 130 on the peripheral region PR, and may cover the top surface 130U2 of the second lower dielectric layer 130 on the peripheral region PR. The capping dielectric layer 150 may have a top surface that is recessed toward the substrate 100 between the data storage patterns DS.

A metal seed layer MSL′ may be formed on the capping dielectric layer 150 to conformally cover the top surface of the capping dielectric layer 150. The metal seed layer MSL′ may cover the recessed top surface of the capping dielectric layer 150. The metal seed layer MSL′ may extend from the capping dielectric layer 150 on the cell region CR on the capping dielectric layer 150 on the boundary region BR and the peripheral region PR. For example, the metal seed layer MSL′ may be formed by a deposition process. The metal seed layer MSL′ may include, for example, at least one of the following: cobalt (Co), iron (Fe), nickel (Ni), and rare-earth metals.

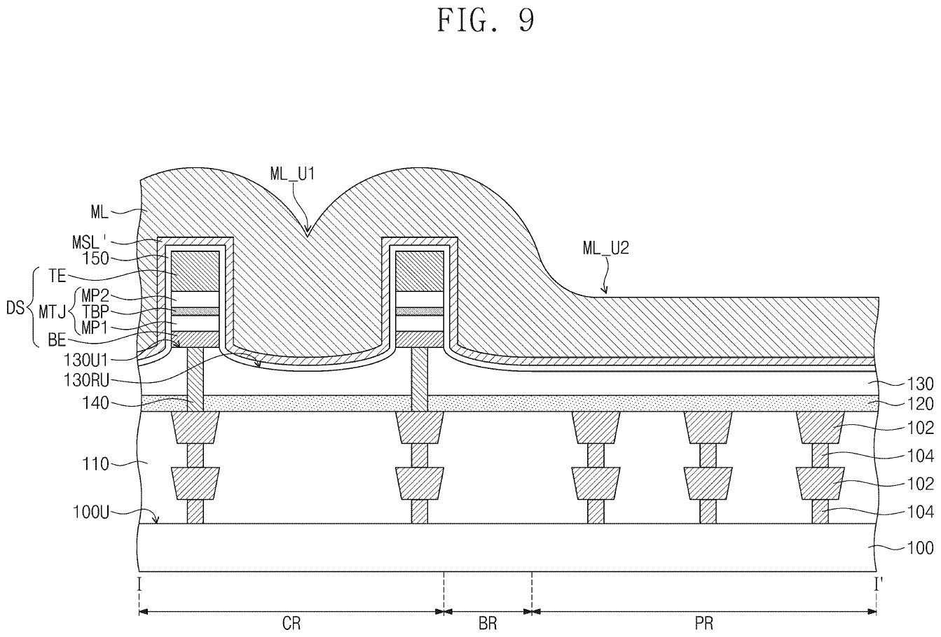

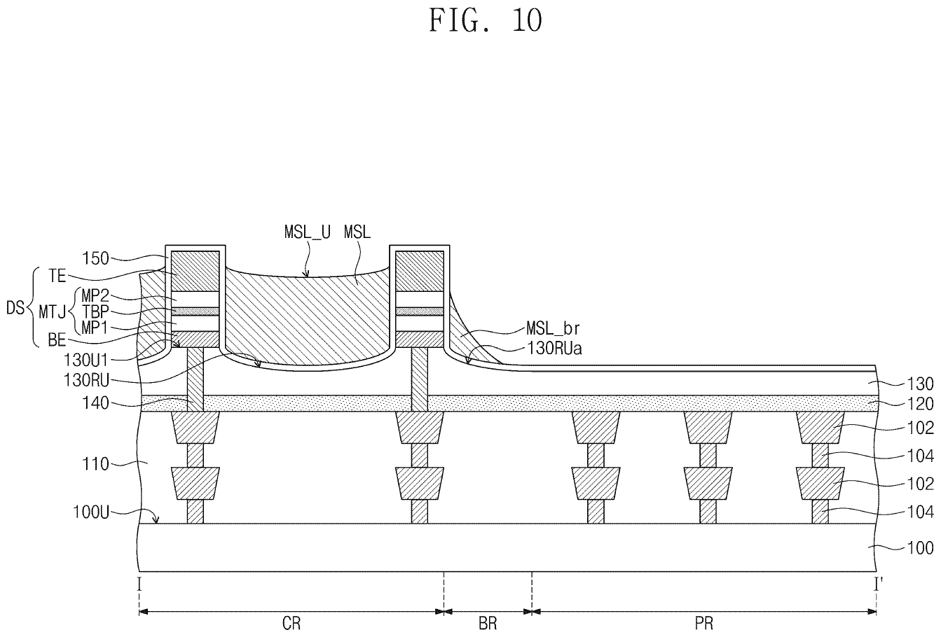

Referring to FIGS. 2 and 9, a metal layer ML may be deposited on the metal seed layer MSL′. The metal layer ML may conformally cover a top surface of the metal seed layer MSL′. For example, the metal layer ML may be formed by performing an electroplating process in which the metal seed layer MSL′ is used as an electrode. For another example, chemical vapor deposition (CVD) may be employed to deposit the metal layer ML on the metal seed layer MSL′. The metal layer ML may include a material the same as or similar to that of the metal seed layer MSL′. The metal layer ML may include a magnetic material, such as at least one of the following: cobalt (Co), iron (Fe), nickel (Ni), and rare-earth metals.

The metal layer ML may be deposited to a thickness equal to or greater than half a distance between neighboring data storage patterns DS. Therefore, the metal layer ML may fill a space between the data storage patterns DS, and the metal layer ML may have a top surface whose minimum level ML_U1 is higher than a level of the top surfaces of the data storage patterns DS.

The metal layer ML may have a convex top surface on the cell region CR and the boundary region BR and a flat top surface on the peripheral region PR. The minimum level ML_U1 of the top surface of the metal layer ML on the cell region CR may be higher than a level ML_U2 of the top surface of the metal layer ML on the peripheral region PR.

Referring to FIGS. 2 and 10, a portion of the metal layer ML may be wet-etched to form a magnetic shield layer MSL having a top surface MSL_U that is recessed toward the substrate 100 between the data storage patterns DS. An etchant used in the wet etching process may have a higher etch selectivity with respect to the metal layer ML and the metal seed layer MSL′ than with respect to the capping dielectric layer 150.

The magnetic shield layer MSL may be formed be on the cell region CR and the boundary region BR by the wet etching process without a separate patterning process on the metal layer ML, and no metallic material may remain on the peripheral region PR. The magnetic shield layer MSL may have the top surface MSL_U that is recessed toward the substrate 100 between the data storage patterns DS. The recessed top surface MSL_U of the magnetic shield layer MSL may be located at a level lower than that of the top surfaces of the data storage patterns DS. The level of the recessed top surface MSL_U of the magnetic shield layer MSL may decrease in a direction from the cell region CR toward the peripheral region PR. In addition, the magnetic shield layer MSL may be integrally formed to extend from the cell region CR onto the boundary region BR. The magnetic shield layer MSL may have one end MSL_br positioned on the boundary region BR.

For example, when the magnetic shield layer MSL is formed by performing an anisotropic etching process that uses plasma without performing the wet etching process, the metal seed layer MSL′ and the metal layer ML including a ferromagnetic substance may not be satisfactorily removed on the peripheral region PR. Therefore, a residual metallic material may electrically interfere with a wiring pattern on the peripheral region PR. Alternatively, in order to form the magnetic shield layer MSL by performing a chemical mechanical polishing (CMP) process without using the wet etching process, separately forming, on the peripheral region PR, a dielectric layer be on the capping dielectric layer 150 to have a height similar to that of the data storage patterns DS can be difficult. As a result, forming the metal seed layer MSL′ and the metal layer ML can complicate the fabrication process.

In contrast, in the present disclosure, the capping dielectric layer 150 may be formed on the cell region CR and the peripheral region PR, and then without forming a separate dielectric layer, the metal seed layer MSL′ and the metal layer ML may be formed on the cell region CR and the peripheral region PR. In addition, without separately performing a patterning process on the metal layer ML, an etching process may be performed to completely remove metallic materials on the peripheral region PR. Forming the magnetic shield layer MSL may be formed on the cell region CR simultaneously with the etching process. Accordingly, it may be possible to simplify a fabrication process.

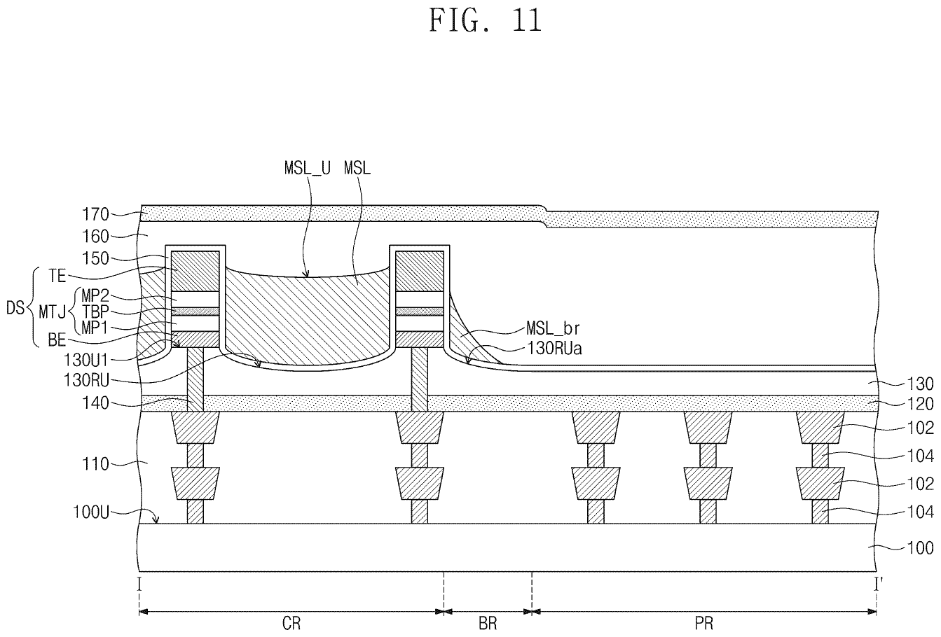

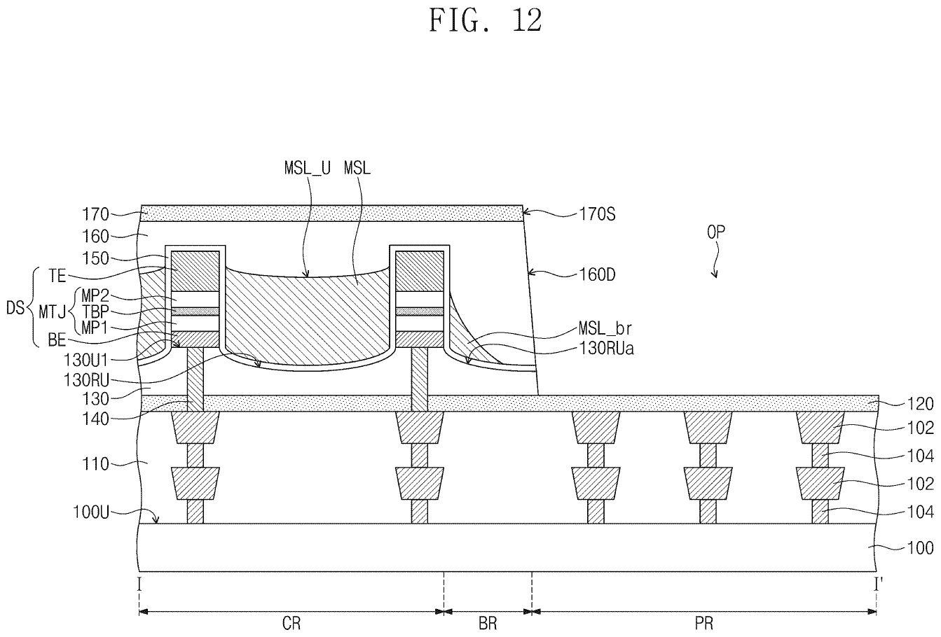

Referring to FIGS. 2 and 11, a cell dielectric layer 160 may be formed on the capping dielectric layer 150. The cell dielectric layer 160 may be formed on the capping dielectric layer 150 on the cell region CR to cover the data storage patterns DS and to fill a space between the data storage patterns DS. The cell dielectric layer 160 may extend onto the capping dielectric layer 150 on the boundary region BR and the peripheral region PR. The cell dielectric layer 160 may be formed by using, for example, a high density plasma chemical vapor deposition (HDP CVD) process.

An upper dielectric layer 170 may be formed on the cell dielectric layer 160. The upper dielectric layer 170 may be formed on the cell dielectric layer 160 on the cell region CR, and may extend onto the cell dielectric layer 160 on the boundary region BR and the peripheral region PR.

Referring to FIGS. 2 and 12, a peripheral opening OP may be formed on the peripheral region PR. The peripheral opening OP may expose the top surface 130U2 of the second lower dielectric layer 130 on the peripheral region PR. On the boundary region BR, the peripheral opening OP may expose a lateral surface 170S of the upper dielectric layer 170, a lateral surface 160S of the cell dielectric layer 160, and a lateral surface of the capping dielectric layer 150.

The formation of the peripheral opening OP may include performing, on the peripheral region PR, a second etching process that removes the upper dielectric layer 170, the cell dielectric layer 160, and the capping dielectric layer 150. For example, the formation of the peripheral opening OP may include forming a cell mask pattern on the upper dielectric layer 170 on the cell region CR, and using the cell mask pattern as an etch mask to perform the second etching process. The cell mask pattern may be, for example, a photoresist pattern. As the second etching process removes the upper dielectric layer 170, the cell dielectric layer 160, and the capping dielectric layer 150 on the peripheral region PR, it may be possible to expose a top surface of the first lower dielectric layer 120 on the peripheral region PR, the lateral surface 170S of the upper dielectric layer 170 on the boundary region BR, the lateral surface 160S of the cell dielectric layer 160, and the lateral surface of the capping dielectric layer 150.

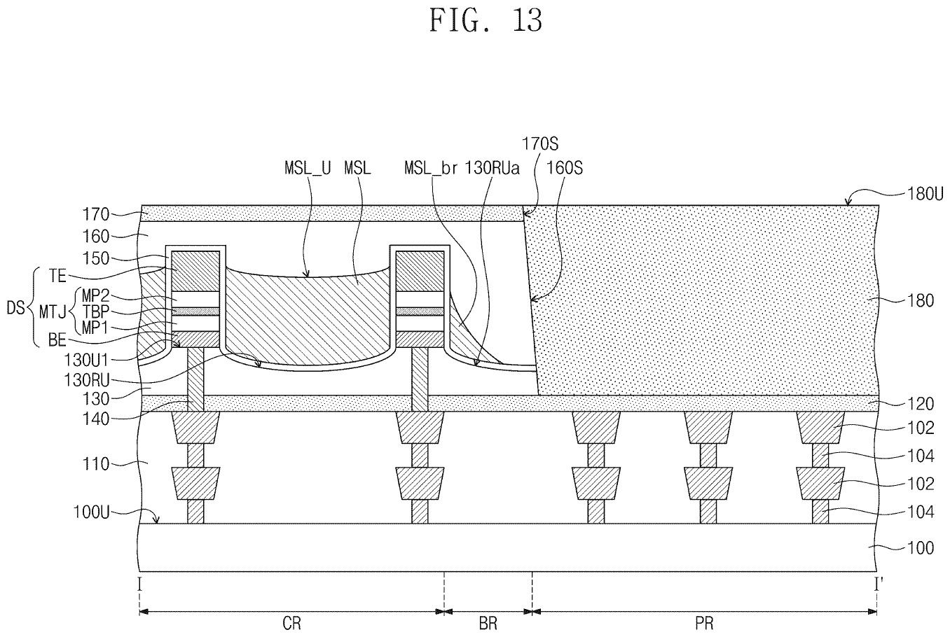

Referring to FIGS. 2 and 13, a peripheral dielectric layer 180 may be formed to fill the peripheral opening OP. The peripheral dielectric layer 180 may be in contact with the top surface of the first lower dielectric layer 120 on the peripheral region PR, the lateral surface of the capping dielectric layer 150 on the boundary region BR, the lateral surface 160S of the cell dielectric layer 160, and the lateral surface 170S of the upper dielectric layer 170. The formation of the peripheral dielectric layer 180 may include, for example, forming a dielectric layer to fill the peripheral opening OP, and planarizing the dielectric layer until a top surface of the upper dielectric layer 170 is exposed. The dielectric layer may be formed by using, for example, a chemical vapor deposition process. The planarization process may be performed by using, for example, at least one selected from an etch-back process and a chemical mechanical polishing process.

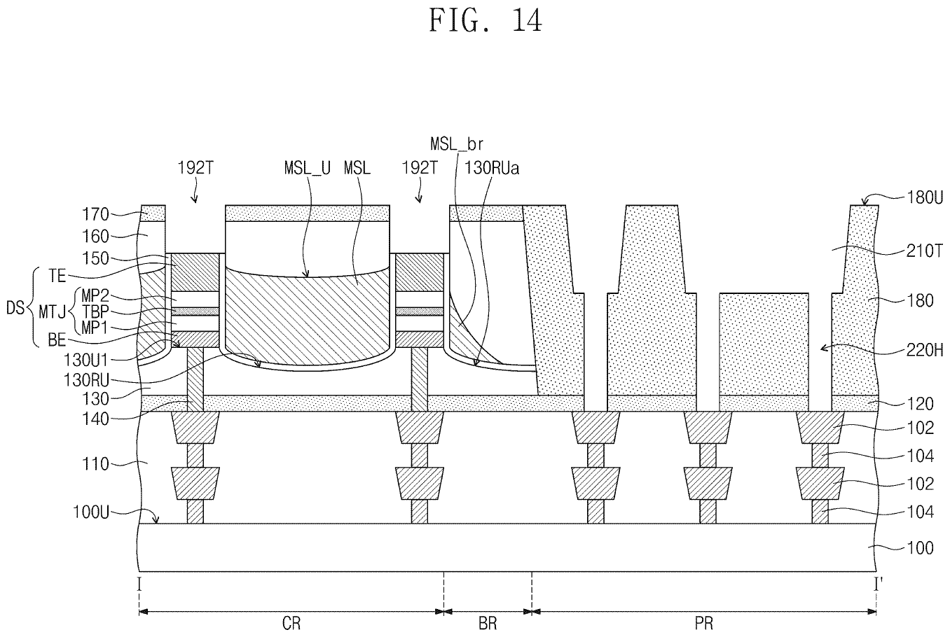

Referring to FIGS. 2 and 14, first cell trenches 192T may be formed on the cell region CR. The first cell trenches 192T may be spaced apart from each other in the first direction D1 and may extend in the second direction D2. Each of the first cell trenches 192T may have a linear shape that extends in the second direction D2, and may expose corresponding data storage patterns DS that are spaced apart from each other in the second direction D2. Each of the first cell trenches 192T may penetrate the upper dielectric layer 170 and an upper portion of the cell dielectric layer 160. Each of the first cell trenches 192T may expose the top electrode TE of each of the corresponding data storage patterns DS.

Peripheral trenches 210T may be formed on the peripheral region PR and in the peripheral dielectric layer 180. Each of the peripheral trenches 210T may penetrate an upper portion of the peripheral dielectric layer 180. Peripheral holes 220H may extend toward the substrate 100 from bottom surfaces of the peripheral trenches 210T. Each of the peripheral holes 220H may penetrate a lower portion of the peripheral dielectric layer 180, and may penetrate the second lower dielectric layer 130 and the first lower dielectric layer 120 on the peripheral region PR. Each of the peripheral holes 220H may expose a top surface of a corresponding one of the uppermost wiring lines 102.

Referring back to FIGS. 2 and 3A, first cell conductive lines 192 may be formed in corresponding first cell trenches 192T. Peripheral conductive line parts 210 may be formed in corresponding peripheral trenches 210T, and peripheral conductive contact parts 220 may be formed in corresponding peripheral holes 220H. The formation of the first cell conductive lines 192, the peripheral conductive line parts 210, and the peripheral conductive contact parts 220 may include, for example, forming, on the upper dielectric layer 170 and the peripheral dielectric layer 180, a conductive layer that fills the first cell trenches 192T, the peripheral trenches 210T, and the peripheral holes 220H, and planarizing the conductive layer until a top surface 170U of the upper dielectric layer 170 is exposed and a top surface 180U of the peripheral dielectric layer 180 is exposed. The planarization process may cause the upper dielectric layer 170, the peripheral dielectric layer 180, and the peripheral conductive line part 210 to respectively have the top surface 170U, the top surface 180U, and a top surface 210U that are located at the same height.

An upper interlayer dielectric layer 200 may be formed on the cell region CR, the boundary region BR, and the peripheral region PR, and may cover the top surface 170U of the upper dielectric layer 170, top surfaces 192U of the first cell conductive lines 192, the top surface 180U of the peripheral dielectric layer 180, and the top surfaces 210U of the peripheral conductive line parts 210.

Second cell conductive lines 196 and conductive contacts 194 may be formed in the upper interlayer dielectric layer 200. The formation of the second cell conductive lines 196 and the conductive contacts 194 may include, for example, forming second cell trenches that penetrate an upper portion of the upper interlayer dielectric layer 200, forming contact holes that penetrate bottom surfaces of the second cell trenches through a lower portion of the upper interlayer dielectric layer 200, forming on the upper interlayer dielectric layer 200 a conductive layer that fills the second cell trenches and the contact holes, and planarizing the conductive layer until a top surface of the upper interlayer dielectric layer 200 is exposed.

In some implementations, a lateral surface of a data storage pattern may be surrounded by a magnetic shield layer that exhibits ferromagnetism. When a magnetic field is formed outside a semiconductor device, most of magnetic flux due to the external magnetic field may pass through the magnetic shield layer and thus there may be a reduction in magnetic flux that passes through the data storage pattern. Therefore, the data storage pattern may be less affected by the external magnetic field.

In addition, a wet etching process may be employed to form the magnetic shield layer. Thus, no magnetic material may remain on a peripheral region, and a fabrication process may be simplified.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device, comprising:
a substrate that includes a cell region and a peripheral region;
a plurality of data storage patterns on the cell region, each of the data storage patterns including a bottom electrode, a magnetic tunnel junction pattern, and a top electrode that are stacked; and
a magnetic shield layer on the cell region and located between the data storage patterns,
wherein the magnetic shield layer surrounds lateral surfaces of the data storage patterns, and
wherein the magnetic shield layer has a top surface that is recessed toward the substrate between the data storage patterns.

2. The semiconductor device of claim 1, wherein the data storage patterns are two-dimensionally arranged along a first direction and a second direction that intersect each other, and
wherein each of the data storage patterns extends through the magnetic shield layer.

3. The semiconductor device of claim 1, wherein the substrate includes a boundary region between the cell region and the peripheral region, and
wherein the magnetic shield layer is on the cell region and the boundary region.

4. The semiconductor device of claim 3, wherein an end of the magnetic shield layer is on the boundary region.

5. The semiconductor device of claim 1, wherein the magnetic shield layer surrounds a lateral surface of the magnetic tunnel junction pattern included in each of the data storage patterns.

6. The semiconductor device of claim 1, wherein the top surface of the magnetic shield layer is at a level higher, along a vertical direction perpendicular to the top surface, than a level of a top surface of the magnetic tunnel junction pattern included in each of the data storage patterns, and
wherein a bottom surface of the magnetic shield layer is at a level lower along the vertical direction than a level of a bottom surface of the magnetic tunnel junction pattern included in each of the data storage patterns.

7. The semiconductor device of claim 1, further comprising a plurality of first cell conductive lines on the data storage patterns on the cell region,
wherein the top surface of the magnetic shield layer is at a level lower, along a vertical direction perpendicular to the top surface, than a level of bottom surfaces of the first cell conductive lines.

8. The semiconductor device of claim 1, further comprising a capping dielectric layer that covers a bottom surface of the magnetic shield layer and is between the lateral surfaces of the data storage patterns and a lateral surface of the magnetic shield layer.

9. The semiconductor device of claim 1, wherein the magnetic shield layer includes at least one of cobalt (Co), iron (Fe), nickel (Ni), or a rare-earth metal.

10. The semiconductor device of claim 1, further comprising:
a plurality of wiring lines on the substrate;
a wiring dielectric layer that covers the wiring lines; and
a plurality of lower electrode contacts that extend through the wiring dielectric layer and connect the wiring lines to the data storage patterns.

11. A semiconductor device, comprising:
a substrate that includes a cell region, a peripheral region, and a boundary region between the cell region and the peripheral region;
a first lower dielectric layer on the substrate;
a second lower dielectric layer on the first lower dielectric layer at the cell region and the boundary region;
a plurality of data storage patterns on the second lower dielectric layer at the cell region, the data storage pattern including a bottom electrode, a magnetic tunnel junction pattern, and a top electrode that are sequentially stacked;
a capping dielectric layer at the second lower dielectric layer, the capping dielectric layer surrounding lateral surfaces of the data storage patterns;
a magnetic shield layer at the capping dielectric layer, the magnetic shield layer surrounding the lateral surfaces of the data storage patterns;
a cell dielectric layer at the cell region and the boundary region, the cell dielectric layer covering the data storage patterns and the magnetic shield layer;
a peripheral dielectric layer at the first lower dielectric layer at the peripheral region; and
a plurality of peripheral wiring patterns in the peripheral dielectric layer, the peripheral wiring patterns extending through the first lower dielectric layer at the peripheral region,
wherein the magnetic shield layer has a top surface that is recessed toward the substrate between the data storage patterns.

12. The semiconductor device of claim 11, wherein the top surface of the magnetic shield layer is at a level higher, along a vertical direction perpendicular to the top surface, than a level of a top surface of the magnetic tunnel junction pattern included in each of the data storage patterns, and
wherein a bottom surface of the magnetic shield layer is at a level lower, along the vertical direction, than a level of a bottom surface of the magnetic tunnel junction pattern included in each of the data storage patterns.

13. The semiconductor device of claim 11, further comprising a plurality of first cell conductive lines on the data storage patterns on the cell region,
wherein the top surface of the magnetic shield layer is at, along a vertical direction perpendicular to the top surface, a level lower than a level of bottom surfaces of the first cell conductive lines.

14. The semiconductor device of claim 11, wherein the top surface of the magnetic shield layer includes:
a first part in contact with the capping dielectric layer; and
a second part spaced apart from the capping dielectric layer and on a center of the top surface,
wherein the first part is at a level higher than a level of the second part.

15. The semiconductor device of claim 11, wherein the peripheral dielectric layer and the peripheral wiring patterns are horizontally spaced apart from the magnetic shield layer.

16. The semiconductor device of claim 11, wherein a lateral surface of the peripheral dielectric layer is in contact with a lateral surface of the cell dielectric layer and a lateral surface of the capping dielectric layer.

17. The semiconductor device of claim 11, further comprising:
a plurality of wiring lines on the substrate;
a wiring dielectric layer that covers the wiring lines; and
a plurality of lower electrode contacts that extend through the wiring dielectric layer and connect the wiring lines to the data storage patterns.

18. A method of fabricating a semiconductor device, comprising:
providing a substrate that includes a cell region, a peripheral region, and a boundary region between the cell region and the peripheral region;
forming, on the substrate, a wiring dielectric layer and a plurality of wiring structures that extend through the wiring dielectric layer;
sequentially stacking, on the wiring dielectric layer, a first lower dielectric layer and a second lower dielectric layer that extend from the cell region onto the boundary region and the peripheral region;
forming, on the cell region, a plurality of data storage patterns each including a bottom electrode, a magnetic tunnel junction pattern, and a top electrode that are sequentially stacked on the second lower dielectric layer;
forming a capping dielectric layer at the second lower dielectric layer at the cell region and the boundary region, wherein the capping dielectric layer cover top surfaces and lateral surfaces of the data storage patterns;
depositing a metal layer that conformally covers a top surface of the capping dielectric layer; and
wet-etching a portion of the metal layer to form a magnetic shield layer having a top surface that is recessed toward the substrate between the data storage patterns.

19. The method of claim 18, wherein forming the magnetic shield layer includes removing the metal layer to expose the capping dielectric layer at the peripheral region.

20. The method of claim 18, wherein the magnetic shield layer is on the cell region and the boundary region, and
wherein the top surface of the magnetic shield layer is at a level lower, along a vertical direction perpendicular to the top surface of the magnetic shield layer, than a level of the top surfaces of the data storage patterns.
